(19) United States
(12) Patent Application Publication
(10) Pub. No.: US 2009/0045402 A1
(43) Pub. Date: Feb. 19, 2009

(54) TFT array substrate and manufacturing method the same

(75) Inventor: Chien-Chung Kuo, Fongyuan City (TW)

Correspondence Address: COOPER & DUNHAM, LLP, 30 Rockefeller Plaza, 20th Floor, NEW YORK, NY, 10112, US

(73) Assignee: Wintek Corporation

(21) Appl. No.: 11/891,722

(22) Filed: Aug. 13, 2007

(51) Int. Cl. H01L 29/06; H01L 21/84

(52) U.S. Cl. 257/59; 438/155; 257/E21.7; 257/E29.003

(57) ABSTRACT

A method of manufacturing TFT array substrate uses only four photolithography processes without any special photo-mask. Pixel electrodes and gate electrodes are made on an upper surface of a substrate in a first photolithography. After that, gate insulating layers, active regions, source and drain doped regions, source and drain electrodes and a passivation layer are sequentially made in second to fourth photolithography processes to complete the TFT array substrate. Therefore, the TFT array substrate is manufactured by four photolithography processes without any special photo-mask, so the processes of the manufacturing process is simplified and the cost is decreased.

### BACKGROUND OF THE INVENTION

1. Field of the Invention

The present invention relates to a TFT array substrate and manufacturing method thereof, especially to a method of manufacturing a TFT array substrate that uses only four exposure masks to produce a new TFT array substrate.

2. Description of Related Art

A TFT array substrate has multiple pixels and contact pads. Each pixel has a thin film transistor, a storage capacitor and a pixel electrode. In present, there are many fabricating ways are used to manufacture the thin film transistor and one of them is back channel etching process technology (BCE).

With reference to FIG. 2A to 2E, only one pixel of a BCE TFT array substrate is shown. The BCE process includes following steps (a) to (j).

(a) A first photolithography process with a mask is used to pattern a first metal layer (61) on the substrate (60). The patterned first metal layer (61) is used as a gate electrode (611) of the thin film transistor and a first electrode (612) of the storage capacitor.

(b) A gate insulating layer (62), an amorphous silicon (a-Si) layer (63) and a doped amorphous silicon (n⁺ a-Si) layer (64) are sequentially and upwardly formed on the substrate (60).

(c) A photolithography process with a mask is used to pattern the a-Si layer (63) and the n⁺ a-Si layer (64) on the substrate (60). The patterned a-Si layer (63) and the n⁺ a-Si layer (64) are only located above the gate electrode (611).

(d) A second metal layer (65) is formed on the substrate (60) to cover the patterned a-Si and the n⁺ a-Si layers (63, 64) and the gate insulating (62).

(e) A third photolithography process with a mask is used to pattern the second metal layer (65). The patterned second metal layer (65) has three parts, that are respectively positioned on the patterned a-Si and the n⁺ a-Si layers (63, 64) and a portion of the gate insulating layer (62) corresponding to the first electrode (612). Therefore, the three parts of the patterned second metal layer (65) have a source electrode (651) and a drain electrode (652) of the thin film transistor and a second electrode (653) of the storage capacitor.

(f) The source and drain electrodes are used as a hard mask to etch through the n⁺ a-Si layer (64) and further etch upper portion of the a-Si layer (63) and then a channel is defined. Therefore, the n⁺ a-Si layer (64) is cut to two independent parts, wherein one of them is used as a source doped region (641) and the other is a drain doped region (642).

(g) A passivation layer (66) is formed on the substrate (60) to cover the patterned second metal (65) and the exposed a-Si layer (63), the exposed the n⁺ a-Si layer (64) and the exposed gate insulating layer (65).

(h) A forth photolithography process with a mask is used to pattern the passivation layer (66) to make the drain electrode (652) and the second electrode (653) are uncovered by the passivation layer (66).

(i) A transparent electrode (67) is formed on the substrate (60) to cover the patterned passivation layer (66), the exposure drain electrode (652) and the second electrode (653).

(j) The transparent electrode (67) is further patterned to form a pixel electrode (67a) of the pixel.

Based on the foregoing description, the BCE TFT array substrate is fabricated by five photolithography processes. After executing each photolithography process, the pattern layer has a pattern shift problem. Therefore, more photolithography processes are used in a fabricating TFT array substrate process, the quality of the TFT array substrate is not good enough and a fabricating cost is high, too. Therefore, other fabricating processes are proposed to decrease numbers of using photolithography processes in one process of fabricating TFT array substrate.

With reference to FIG. 3A to 3E, another conventional method of manufacturing liquid crystal display device is shown. After the first photolithography process, the first metal layer is patterned to used as the gate electrode (60a) of the thin film transistor. After that, the gate insulating layer (50), the a-Si layer (80a), the n⁺ a-Si layer (80b) and the second metal layer (170) are formed sequentially and upwardly on the substrate (10). Before using the second photolithography process, a photoresist layer (88) is formed on the second metal layer (170) and a special photo-mask (25) is prepared. The special photo-mask has a light shielding area (25a), a light transmitting area (25b) and a diffraction light exposing area (25c). After the second photolithography process with the special photo-mask (25), an area of the photoresist layer (88) corresponding to the diffraction light exposing area (25c) is exposed incompletely. Therefore, the patterned photoresist layer (88a) has a thin portion after developing the exposed photoresist and the thin portion is corresponding to the gate electrode (60a). In next following etching processes, the portions of the second metal layer (170), the n⁺ a-Si layer (80b) and the a-Si layer (80a) are uncovered by the pattern photoresist layer (88a) are etched. In addition, the portions of the second metal layer (170) and the n⁺ a-Si layer (80b), that are covered by the thin portion, are respectively etched to form two independent parts. Therefore, the two independent parts of the second metal layer (170) are used as a source electrode and a drain electrode of the thin film transistor. The two independent parts of the n⁺ a-Si layer are used as a source doped region (70a) and a drain doped region (70b) of the thin film transistor.

Based on the foregoing description, the manufacturing method provides the second photolithography process to integrate the second and third photolithography processes of the foregoing BCE process shown in FIGS. 2B to 2C. Therefore, to complete the pixel of the TFT film, only two photolithography processes are required after the process shown in FIG. 3E. However, the special photo-mask is used to save one photolithography process in manufacturing the TFT array substrate process, but the cost of the special photo-mask is higher than that of a general mask and the yield of process is decreased by using the special photo-mask.

### SUMMARY OF THE INVENTION

The objectives of the present invention include providing a TFT array substrate and method of manufacturing the same that has only four photolithography processes without special photo-mask to manufacture the TFT array substrate.

The method of manufacturing TFT array substrate in accordance with the present invention uses only four photolithography processes without any special photo-mask. Pixel electrodes and gate electrodes are made on an upper surface of a substrate in a first photolithography. After that, gate insulating layers, active regions, source and drain doped regions, source and drain electrodes and a passivation layer are sequentially made in second to fourth photolithography processes to complete the TFT array substrate. Therefore, the TFT array substrate is manufactured by four photolithography processes without any special photo-mask, so the processes of the manufacturing process is simplified and the cost is decreased.

Other objectives, advantages and novel features of the invention will become more apparent from the following detailed description when taken in conjunction with the accompanying drawings.

### BRIEF DESCRIPTION OF THE DRAWINGS

FIGS. 1A to 1F are cross sectional views illustrating detailed processes of a method of manufacturing TFT array substrate in accordance with the present invention;

FIGS. 2A to 2E are cross sectional views illustrating detailed processes of a manufacturing method with five photolithography processes in accordance with the prior art; and

FIGS. 3A to 3E are sectional views illustrating detailed processes of a manufacturing method in accordance with the prior art.

### DETAILED DESCRIPTION OF THE PREFERRED EMBODIMENT

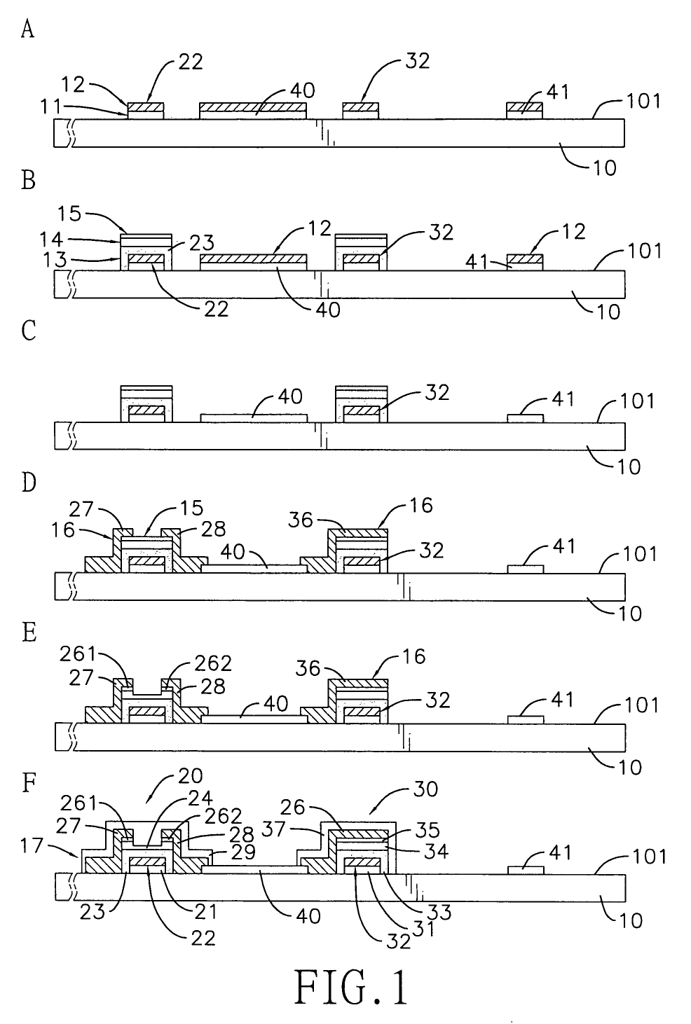

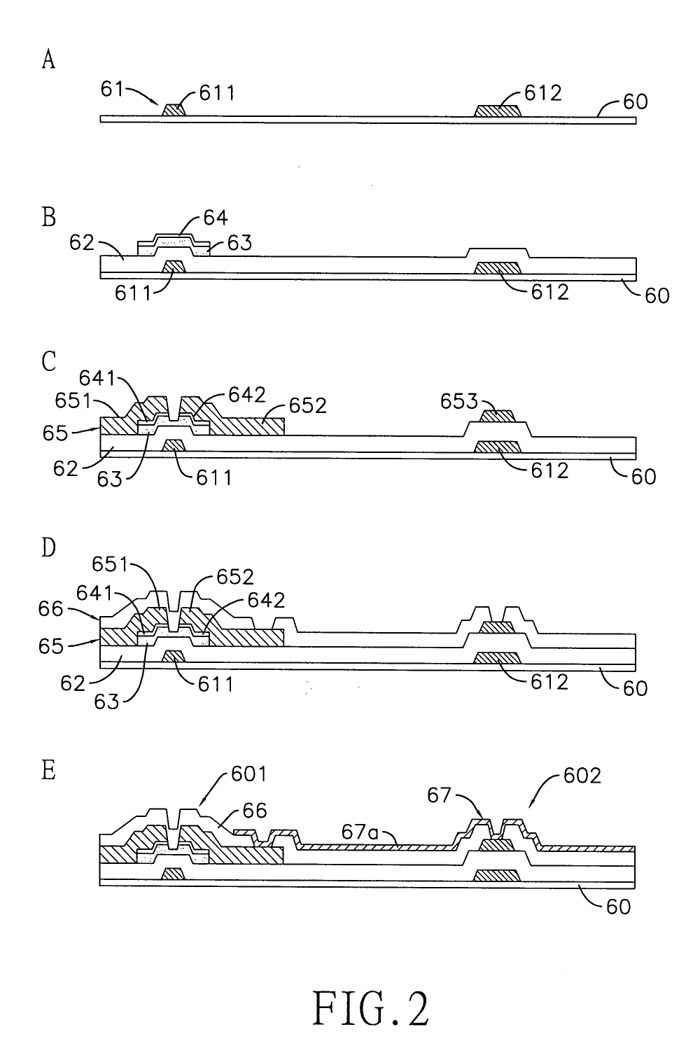

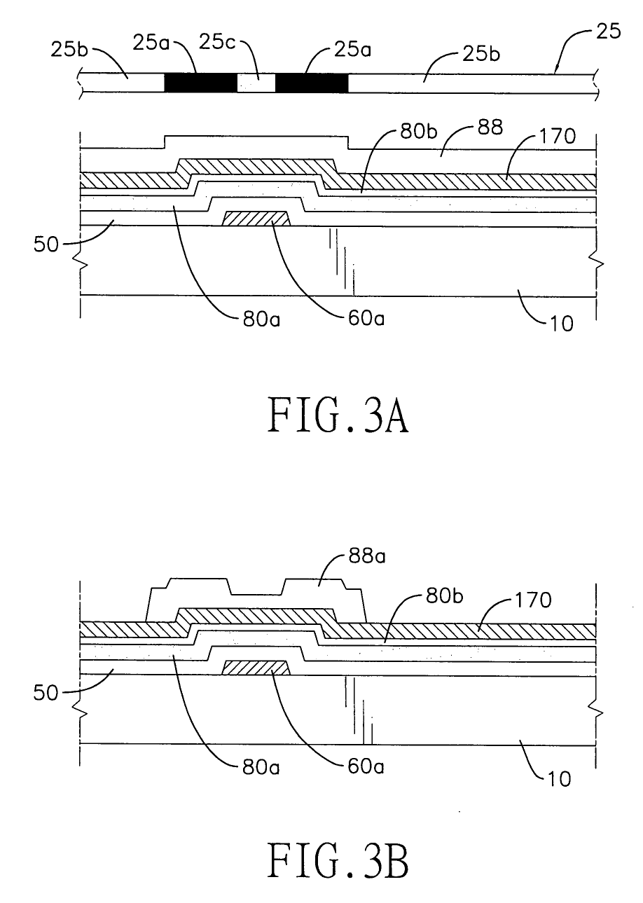

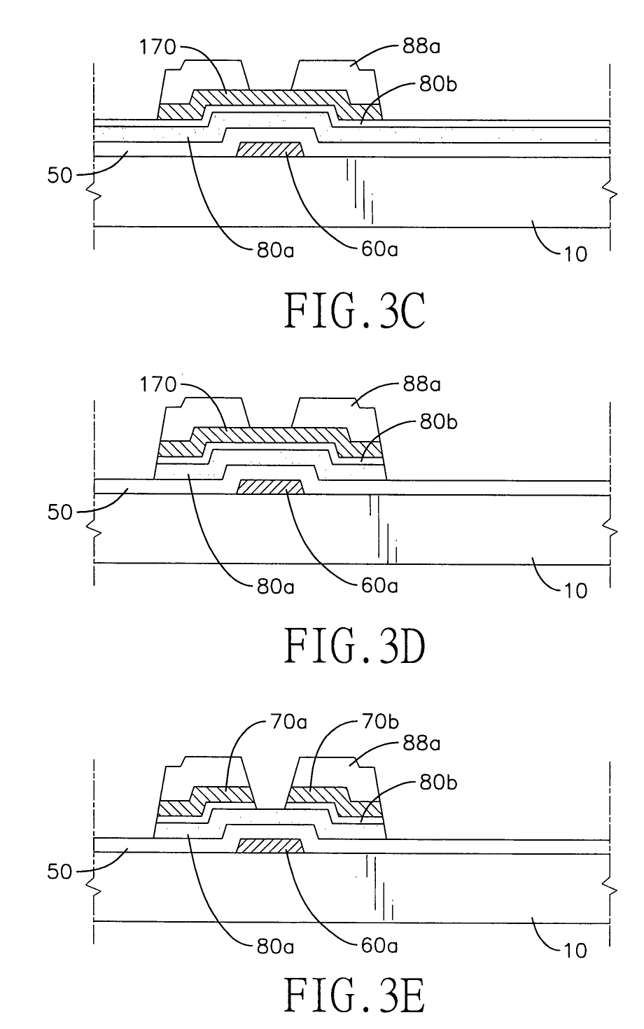

A TFT array substrate has multiple pixels and multiple contact pads. Each pixel has a thin film transistor, a storage capacitor and a pixel electrode. With reference to FIGS. 1A to 1F, only one pixel and one contact pad of the TFT film and one contact pad are shown to describe detailed processes of a method of manufacturing the TFT array substrate.

With first reference to FIG. 1A, a substrate (10) having an upper surface (101) on which a transparent electrode layer (11) and a first metal layer (12) are formed on the upper surface (101) sequentially and upwardly. After a first photolithography process with a mask, a patterned transparent electrode layer (11) and a patterned first metal layer (12) are formed. Therefore, a double-layer gate electrode (22) of the thin film transistor, a double-layer first electrode (32) of the storage capacitor, a double-layer pixel electrode and a double-layer contact pad are formed. In the first photolithography process, the pixel electrode is firstly formed on the substrate.

With further reference to FIG. 1B, a triple-layer structure is formed on the substrate (10). The triple-layer structure is a gate insulating layer (13), an a-Si layer (14), and a n⁺ a-Si layer (15) and are sequentially and upwardly formed on the substrate (10). The gate insulating layer (13) covers the pattern transparent electrode layer (11) and the pattern first metal layer (12). The a-Si layer (14) covers on the gate insulating layer (13) and the n⁺ a-Si layer (15) further covers the a-Si layer (14). After a second photolithography process, the triple-layer structure is patterned to retain a first and second portions of the triple-layer structure corresponding to the double-layer gate and first electrodes of the storage capacitor (22, 32), and other portions of the triple-layer structure are removed. The a-Si layers of the first and second potions of the patterned triple-layer structure are respectively used as an active region of the thin film transistor and a dielectric layer of the storage capacitor.

With further reference to FIG. 1C, two upper patterned first metal layers of the double-layer pixel electrode and the contact layer are removed to make the patterned transparent electrode layers are exposed and respectively used as the pixel electrode (40) and the contact pad (41).

With further reference to FIG. 1D, a second metal layer (16) is formed on the substrate (10) to cover the first and second portions of the patterned triple-layer structure, the pattern pixel electrode (40) and the contact pad (41). After that, a third photolithography process is executed to pattern the second metal layer (16). The patterned second metal layer (16) includes a source electrode (27), a drain electrode (28), and a second electrode (36) of the storage capacitor. The drain electrode (28) and the second electrode (36) are connected electronically through the pixel electrode (40).

Since the source and drain electrodes (27, 28) are formed in the third photolithography process, they are also used as a hard mask to etch downwardly the patterned n⁺ a-Si layer (15) and further etch upper portion of the a-Si layer (14) to define a channel. Therefore, a source doped region (261) and a drain doped region (262) are formed to complete the thin film transistor with further reference to FIG. 1E.

With further reference to FIG. 1F, a passivation layer (17) is formed on the substrate (10). After a fourth photolithography process, multiple openings defined to the passivation layer (17) are corresponding to the pixel electrode (40) and the contact pad (41). Therefore, the patterned passivation layer (29, 37) covers the thin film transistor (20) and the storage capacitor (30) to complete the TFT array substrate.

Based on the foregoing description, the method of manufacturing the TFT array substrate only uses four photolithography processes without special photo-mask, so manufacturing processes are simplified and manufacturing cost is down.

With reference to FIG. 1F, a new TFT array substrate is manufactured by the manufacturing process in accordance with the present invention has a substrate (10), multiple thin film transistors (20), multiple storage capacitors (30), multiple pixel electrodes (40) and a passivation layer (29, 37). However, in FIG. 1F only shows one thin film transistor (20), one storage capacitor (30), and one pixel electrode (40)

The thin film transistor (20) is formed on an upper surface (101) of the substrate (10) and has a double-layer gate electrode (22), a gate insulating layer (23), an a-Si layer (24), a source doped region (261), a drain doped region (262), a source electrode (27) and a drain electrode (28), which are sequentially and upwardly formed on the upper surface (101). In addition, the source and drain electrodes (27, 28) are respectively located on the source and drain doped regions (261, 262).

The storage capacitor (30) is also formed on the upper surface (101) of the substrate (10) and has a double-layer first electrode (32), a triple-layer dielectric layer and a second electrode (36), which are formed sequentially and upwardly on the upper surface (101). The dielectric layer is a triple-layer structure consisted of an insulating layer, an a-Si layer and a n⁺ a-Si layer (33, 34, 35).

The pixel electrode (40) is formed on the upper surface (101) of the substrate (10) directly and connected to the drain electrode (28) of the thin film transistor (20) and the second electrode (36) of the storage capacitor (30).

The passivation layer (29, 37) covers the thin film transistor (20) and the storage capacitor (30).

Further, since the pixel electrode (40) and the contact pad (41) are made in the same process, the pixel electrode (40) and the contact pad (41) are made of the same material, such as ITO or IZO.

Based on the foregoing description, the TFT array substrate differs from a general one, since the pixel electrode is formed on the upper surface of the substrate directly. Therefore, the manufacturing method in accordance with the present invention saves one photolithography process to form the pixel electrode. In addition, the source and drain electrodes are used as the hard mask to etch to the channel. Therefore, the present invention reduces a manufacturing cost.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A method of manufacturing TFT array substrate, comprising steps of:
forming sequentially and upwardly a transparent electrode layer and a first metal on an upper surface of a substrate;
using a first photolithography process to pattern the transparent electrode layer and the first metal to form multiple double-layer structures, wherein the multiple double-layer structures are used to respectively define gate electrodes of thin film transistors, first electrodes of storage capacitors and multiple double-layer pixel electrode;
forming sequentially and upwardly a gate insulating layer, an a-Si layer and a n⁺ a-Si layer on the substrate to cover the multiple double-layer structures;
using a second photolithography process to pattern the gate insulating layer, the a-Si layer and n⁺ a-Si layer to form multiple triple-layer structures, each of which is located on corresponding gate electrode, wherein the multiple triple-layer structures are used to respectively define active regions of the thin film transistors and dielectric layers of the storage capacitors;
forming a second metal layer on the substrate to cover the upper surface of the substrate, the double-layer structures and the multiple triple-layer structures;
using a third photolithography process to pattern the second metal layer to form multiple source electrodes, multiple drain electrodes and multiple second electrodes of storage capacitors, wherein each drain electrode and each second electrode of storage capacitors are connected electronically through the corresponding pixel electrode, and the n⁺ a-Si layer is etched to separate a source doped region and a drain doped region; and
using a fourth photolithography process after depositing a passivation layer on the substrate to pattern the passivation layer to define multiple openings corresponding to the pixel electrodes and the contact pads.

2. The method as claimed in claim 1, wherein in the first photolithography process, multiple double-layer structures are further used to define double-layer contact pads.

3. The method as claimed in claim 2, wherein in the second photolithography process, the patterned first metal layers of the double-layer pixel electrode and the double-layer contact pads are removed to form the single layer pixel electrodes and the contact pads.

4. The method as claimed in claim 1, wherein the transparent electrode layer is made of ITO or IZO.

5. The method as claimed in claim 2, wherein the transparent electrode layer is made of ITO or IZO.

6. The method as claimed in claim 3, wherein the transparent electrode layer is made of ITO or IZO.

7. A TFT array substrate having a substrate, and multiple pixels deposited on the substrate in matrix, wherein each pixel comprises:
a thin film transistor formed on an upper surface of the substrate and having a gate electrode, a gate insulating layer, an a-Si layer, a source doped region, a drain doped region, a source electrode and a drain electrode, which are sequentially and upwardly formed on the upper surface, wherein the gate electrode is consisted of a transparent electrode layer and a first metal layer, and the source and drain electrodes are respectively located on the source and drain doped regions;
a storage capacitor formed on the upper surface of the substrate and having a first electrode, a dielectric layer and a second electrode, which are formed sequentially and upwardly on the upper surface;
a pixel electrode formed on the upper surface of the substrate directly and connected to the drain electrode of the thin film transistor and the second electrode of the storage capacitor; and
a multiple passivation layers respectively covering the thin film transistor and the storage capacitor.

8. The TFT array substrate as claimed in claim 7, wherein the dielectric layer is a triple-layer structure consisted of an insulating layer, an a-Si layer and a n⁺ a-Si layer.

9. The TFT array substrate as claimed in claim 7, wherein the first electrode is a double-layer structure consisted of a transparent electrode and a first metal layer.

10. The TFT array substrate as claimed in claim 8, wherein the first electrode is a double-layer structure consisted of a transparent electrode and a first metal layer.

11. The TFT array substrate as claimed in claim 7, further comprising multiple contact pads formed on the upper surface of the substrate, each of which is made of a transparent electrode layer.

12. The TFT array substrate as claimed in claim 8, further comprising multiple contact pads formed on the upper surface of the substrate, each of which is made of a transparent electrode layer.

13. The TFT array substrate as claimed in claim 9, further comprising multiple contact pads formed on the upper surface of the substrate, each of which is made of a transparent electrode layer.

14. The TFT array substrate as claimed in claim 7, wherein the source and drain electrodes are made of a second metal layer.

15. The TFT array substrate as claimed in claim 7, wherein the second electrode of the storage capacitor is made of a second metal layer.

16. The TFT array substrate as claimed in claim 7, wherein the transparent electrode layer is made of ITO or IZO.
